(19) United States
(12) Patent Application Publication
(10) Pub. No.: US 2015/0302639 A1
(43) Pub. Date: Oct. 22, 2015

(54) METHOD AND SYSTEM FOR CREATING ENHANCED IMAGES INCLUDING AUGMENTED REALITY FEATURES TO BE VIEWED ON MOBILE DEVICES WITH CORRESPONDING DESIGNS

(71) Applicant: Augmentecture, Inc., Montrose, CA (US)

(72) Inventors: Alen Malekian, Glendale, CA (US); Zarik Boghossian, Glendale, CA (US)

(73) Assignee: Augmentecture, Inc.

(21) Appl. No.: 14/668,944

(22) Filed: Mar. 25, 2015

Related U.S. Application Data
(60) Provisional application No. 61/970,593, filed on Mar. 26, 2014.

(51) Int. Cl. G06T 17/00; H04L 29/06; G06T 19/00; G06F 17/50

(52) U.S. Cl. CPC G06T 17/00; G06F 17/5004; H04L 67/42; G06T 19/006

(57) ABSTRACT

Methods and/or systems are provided that may create enhanced images including augmented reality features to be viewed on mobile devices with corresponding designs utilizing a scannable marker that is read by an optical reader on the mobile device.

### BACKGROUND

1. Field

The subject matter disclosed herein relates to a method and/or system for creating computer-generated augmented images or other content that can be viewed in combination with a hard copy print or a viewable document of a corresponding digital image. Particularly, the subject matter relates to the viewing of computer-generated model over a hard copy of a plan (or superimposed on an electronic document) after a computing device reads and/or scans a marker or unique link.

2. Information/Background of Information

Conventional computer models of objects are viewed primarily on a desktop computer, laptop computer or table kind devices. Other conventional viewing options for computer generated models are hard copy of the image or images. In the architecture industry, as a normal process of design of a typical building structure, one begins with the design drawings of the particular floor plan of a space, or a design of an object. By the use of some latest drafting software, one can generate computer models as the floor plan is being developed. One of the latest trends in the architectural industry is the use of BIM (“Building Information Modeling”), which allows the user to develop a plan and a corresponding three-dimensional model of a building or structure.

While the techniques of viewing models on computer and or hard copy of an image conveys the idea of the space across, there is a need for an augmented viewing process to allow the user the freedom of viewing the actual model in relation to its plan at any perspective and/or angle and any scale on a hand held or mobile device (including without limitation, mobile computing devices, mobile phones, tablets and other similar devices).

3. Summary of the Invention

The object of the present invention of the augmentation of the model with the actual plan is to allow the ease of viewing the model by any user at any time, at any place, at any viewing perspective, or at any scale. This may (among other things) facilitate an understanding of the design and engineering elements of the building or structure depicted by the plan and model. It is also an object of the present invention to provide unique presentation technique to architectural and engineering industry. Another object of the present invention is to allow the augmentation of the model and the plan to be incorporated into commonly used computer drafting software and applications that are currently used in the industry. A specific object of the invention is to allow users to view the hard copy of the vectored two dimension plan of a building, structure or an object be viewed in a three dimensional model by the use of hand held device that is equipped with an optical viewing apparatus such as a smartphone or table camera, an attached camera, or marker reading device.

The method and the system of this invention center around the invention concept of providing the user the ability to view augmented content, such as a three-design model associated with a specific design plan, by bringing a unique marker within the field of view of a handheld device (or other mobile or computing device) that is equipped with an optical viewing apparatus (e.g., camera or scanner). The invention will allow multiple or specific users to view augmented content associated with a unique marker, such as in the case of a three-dimensional model of a specific vectored plan of a design building or a structure. The invention will process the vectored plan of a design building or structure with a specific marker that will be incorporated as part of the print document. For purposes of clarity, in the foregoing example, the user of the handheld device would be able to view augmented image of the three-dimensional model by bringing the vectored plan containing a unique marker within the field of view of the handheld device. The invention includes (without limitation) a process by which a unique and specific marker will be incorporated on the printed copy of the vectored plan of a design building or structure. The computer generated (three-dimensional) model of a specific plan will be placed, stored or saved in a folder or directory which will be referenced and linked to the specific vectored plan and the unique marker associated with the vectored plan (which marker will be placed on the vectored design plan). The invention will allow specific or multiple users to access the computer model by the way of hand held device which will have optical apparatus (e.g., cameras or scanners) that has been given rights by the administrator to be accessed by the hand held device. The invention will allow users to access and view the augmented model of the design by the use a specific application that can be downloaded via the internet and installed on the handheld or mobile device.

The invention will enable the user of a handheld device to use an application to view the computer generated model associated with a specific design plan by bringing the unique marker embedded on the design plan within the field of view of the handheld device. The invention will allow the user to hold the hand held apparatus with optical capabilities over the vectored plan with an embedded marker and view augmented model over the exact points of reference of the vectored plan which the model will be viewed over exact points of the vectored plan and user will be able to view model at any perspective. The hand held device will also allow the user to rotate model over the specific vectored plan and view any perspective or angle of the model.

When the user activates the above-referenced application on the handheld device with the optical apparatus, the user will be asked to log in to a directory in which the computer-generated model will be stored and linked to the hard copy of the vectored plan with a special marker that the user will have in the user's possession. Such computer-generated model will be viewable on the handheld device by bringing the special marker placed on the hard copy of the vectored plan within the field of view of the optical apparatus (e.g., camera and scanner) on the handheld device. The invention of this process will convert the conventional viewing of a two-dimensional design plan into viewing the design plan in conjunction with the three-dimensional model in augmented reality by linking the augmented content (i.e. the three-dimensional model) to the special marker or unique link that is placed on the hard copy of the vectored plan or is embedded into an electronic document and viewable by a user of the smart apparatus.

The method of this invention is particularly suited for architectural, design, and engineering industry that “will allow end users to view the three-dimensional models (that are conventionally viewed on a computer device at a stationery location or as a hard copy of the unique image) in augmented format. Viewing in augmented format will allow the user to view the model of a particular vectored plan with its unique marker at any location in any environment as long as the special marker is brought within the field of view of the optical apparatus on the handheld device.

The present invention advances the art of presentation and viewing capabilities of the design projects for architects, engineers and designers to the next level of augmented reality and will allow end users to view the three-dimensional model of any structure in conjunction with the vectored two dimensional format hard copy media. It will provide an additional tool for designers to convey their design ideas to anyone at any location desired. It will also provide users with a new viewing perspective and enhanced viewing capability. The invention will in turn (among other things) enhance an understanding of the design, engineering and structural elements of a building or structure.

### BRIEF DESCRIPTION OF DRAWINGS

Claimed subject matter is particularly pointed out and distinctly claimed in the concluding portion of the specification. However, both as to organization and/or method of operation, together with objects, features, and/or advantages thereof, it may be best understood by reference to the following detailed description if read with the accompanying drawings in which:

FIG. 1 is a representation of a digital image generated by a computer of a design plan;

FIG. 2 is a representation of a three-dimensional model of a building generated by a computer;

FIG. 3 is an illustration of an example of a print dialog box incorporating print and save process;

FIG. 4 is an illustration of an example of the floor plan of the building that is printed with the special marker which will be linked to a specific 3D model;

FIG. 5 is the illustration of an example of the printed hard copy of the drawn plan (which contains the special marker);

FIG. 6A is an illustration of an example screenshot of the hand held application and a block diagram of modules within the central server;

FIGS. 6B-6D is an illustration of screen shots of the mobile device software application including augmented reality features.

FIG. 7 is the illustration of an example of the application deployed and used to view model of the specific plan by the hand held device;

FIG. 8 is a diagram showing the entire system and process for creating and using augmented reality content;

FIG. 9 is a flowchart 900 detailing a method of generating an enhanced image file in accordance with an embodiment;

FIG. 10 illustrates a computing device according to an embodiment; and

FIG. 11 is a schematic diagram illustrating a client device implementation of a computing device in accordance with embodiments of the present disclosure

Reference is made in the following detailed description to accompanying drawings, which form a part hereof, wherein like numerals may designate like parts throughout to indicate corresponding and/or analogous components. It will be appreciated that components illustrated in the figures have not necessarily been drawn to scale, such as for simplicity and/or clarity of illustration. For example, dimensions of some components may be exaggerated relative to other components. Further, it is to be understood that other embodiments may be utilized. Furthermore, structural and/or other changes may be made without departing from claimed subject matter. It should also be noted that directions and/or references, for example, up, down, top, bottom, and so on, may be used to facilitate discussion of drawings and/or are not intended to restrict application of claimed subject matter. Therefore, the following detailed description is not to be taken to limit claimed subject matter and/or equivalents.

### DETAILED DESCRIPTION

References throughout this specification to one implementation, an implementation, one embodiment, an embodiment and/or the like means that a particular feature, structure, and/or characteristic described in connection with a particular implementation and/or embodiment is included in at least one implementation and/or embodiment of claimed subject matter. Thus, appearances of such phrases, for example, in various places throughout this specification are not necessarily intended to refer to the same implementation or to any one particular implementation described. Furthermore, it is to be understood that particular features, structures, and/or characteristics described are capable of being combined in various ways in one or more implementations and, therefore, are within intended claim scope, for example. In general, of course, these and other issues vary with context. Therefore, particular context of description and/or usage provides helpful guidance regarding inferences to be drawn.

Subject matter will now be described more fully hereinafter with reference to the accompanying drawings, which form a part hereof, and which show, by way of illustration, specific example embodiments. Subject matter may, however, be embodied in a variety of different forms and, therefore, covered or claimed subject matter is intended to be construed as not being limited to any example embodiments set forth herein; example embodiments are provided merely to be illustrative. Likewise, a reasonably broad scope for claimed or covered subject matter is intended. Among other things, for example, subject matter may be embodied as methods, devices, components, or systems. Accordingly, embodiments may, for example, take the form of hardware, software, firmware or any combination thereof (other than software per se). The following detailed description is, therefore, not intended to be taken in a limiting sense.

Likewise, in this context, the terms “coupled”, “connected,” and/or similar terms are used generically. It should be understood that these terms are not intended as synonyms. Rather, “connected” is used generically to indicate that two or more components, for example, are in direct physical, including electrical, contact; while, “coupled” is used generically to mean that two or more components are potentially in direct physical, including electrical, contact; however, “coupled” is also used generically to also mean that two or more components are not necessarily in direct contact, but nonetheless are able to co-operate and/or interact. The term coupled is also understood generically to mean indirectly connected, for example, in an appropriate context.

The terms, “and”, “or”, “and/or” and/or similar terms, as used herein, include a variety of meanings that also are expected to depend at least in part upon the particular context in which such terms are used. Typically, “or” if used to associate a list, such as A, B or C, is intended to mean A, B, and C, here used in the inclusive sense, as well as A, B or C, here used in the exclusive sense. In addition, the term “one or more” and/or similar terms is used to describe any feature, structure, and/or characteristic in the singular and/or is also used to describe a plurality and/or some other combination of features, structures and/or characteristics. Likewise, the term “based on” and/or similar terms are understood as not necessarily intending to convey an exclusive set of factors, but to allow for existence of additional factors not necessarily expressly described. Of course, for all of the foregoing, particular context of description and/or usage provides helpful guidance regarding inferences to be drawn. It should be noted that the following description merely provides one or more illustrative examples and claimed subject matter is not limited to these one or more illustrative examples; however, again, particular context of description and/or usage provides helpful guidance regarding inferences to be drawn.

As used herein, a “cloud” is used in an art-recognized manner and can refer to a collection of centrally managed resources such as networked hardware and/or software systems and combinations thereof provided and maintained by an entity, wherein the collection of resources can be accessed by a user via wired or wireless access to a network that may be public or private, such as, for example, a global network such as the Internet. Such centralized management and provisioning of resources can provide for dynamic and on-demand provisioning of computing and/or storage to match the needs of a particular application. The cloud may include a plurality of servers, general or special purpose computers, as well as other hardware such as storage devices. The resources can include data storage services, database services, application hosting services, word processing services, payment remitting services, and many other information technological services that are conventionally associated with personal computers or local and remote servers. Moreover, in one aspect, the resources can be maintained within any number of distributed servers and/or devices as discussed in more detail below. Thus, the present disclosure discusses a system that performs data storage and application hosting operations within a cloud computing environment in order for a user to manage his/her personal information from a central online location.

In the accompanying drawings, some features may be exaggerated to show details of particular components (and any size, material and similar details shown in the figures are intended to be illustrative and not restrictive). Therefore, specific structural and functional details disclosed herein are not to be interpreted as limiting, but merely as a representative basis for teaching one skilled in the art to variously employ the disclosed embodiments.

The present invention is described below with reference to block diagrams and operational illustrations of methods and devices to select and present media related to a specific topic. It is understood that each block of the block diagrams or operational illustrations, and combinations of blocks in the block diagrams or operational illustrations, can be implemented by means of analog or digital hardware and computer program instructions. These computer program instructions or logic can be provided to a processor of a general purpose computer, special purpose computer, ASIC, or other programmable data processing apparatus, such that the instructions, which execute via the processor of the computer or other programmable data processing apparatus, implements the functions/acts specified in the block diagrams or operational block or blocks.

For the purposes of this disclosure a “network” should be understood to refer to a network that may couple devices so that communications may be exchanged, such as between a server and a client device or other types of devices, including between wireless devices coupled via a wireless network, for example. A network may also include mass storage, such as network attached storage (NAS), a storage area network (SAN), or other forms of computer or machine readable media, for example. A network may include the Internet, one or more local area networks (LANs), one or more wide area networks (WANs), wire-line type connections, wireless type connections, cellular or any combination thereof. Likewise, sub-networks, which may employ differing architectures or may be compliant or compatible with differing protocols, may interoperate within a larger network. Various types of devices may, for example, be made available to provide an interoperable capability for differing architectures or protocols. As one illustrative example, a router may provide a link between otherwise separate and independent LANs.

For the purposes of this disclosure the term “server” should be understood to refer to a service point which provides processing, database, and communication facilities. By way of example, and not limitation, the term “server” can refer to a single, physical processor with associated communications and data storage and database facilities, or it can refer to a networked or clustered complex of processors and associated network and storage devices, as well as operating software and one or more database systems and applications software which support the services provided by the server.

A computing device may be capable of sending or receiving signals, such as via a wired or wireless network, or may be capable of processing or storing signals, such as in memory as physical memory states, and may, therefore, operate as a server. Thus, devices capable of operating as a server may include, as examples, dedicated rack-mounted servers, desktop computers, laptop computers, set top boxes, integrated devices combining various features, such as two or more features of the foregoing devices, or the like. Servers may vary widely in configuration or capabilities, but generally a server may include one or more central processing units and memory. A server may also include one or more mass storage devices, one or more power supplies, one or more wired or wireless network interfaces, one or more input/output interfaces, or one or more operating systems, such as Windows Server, Mac OS X, Unix, Linux, FreeBSD, or the like.

Throughout the specification and claims, terms may have nuanced meanings suggested or implied in context beyond an explicitly stated meaning. Likewise, the phrase “in one embodiment” as used herein does not necessarily refer to the same embodiment and the phrase “in another embodiment” as used herein does not necessarily refer to a different embodiment. It is intended, for example, that claimed subject matter include combinations of example embodiments in whole or in part. In general, terminology may be understood at least in part from usage in context. For example, terms, such as “and”, “or”, or “and/or,” as used herein may include a variety of meanings that may depend at least in part upon the context in which such terms are used. Typically, “or” if used to associate a list, such as A, B or C, is intended to mean A, B, and C, here used in the inclusive sense, as well as A, B or C, here used in the exclusive sense. In addition, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

A clear understanding of the key features of the above-summarized invention may be had by reference to the appended drawings, which illustrate the method and system of the invention, although it will be understood that such drawings depict preferred embodiments of the invention and, therefore, are not to be considered as limiting its scope with regard to other embodiments that the invention is capable of contemplating.

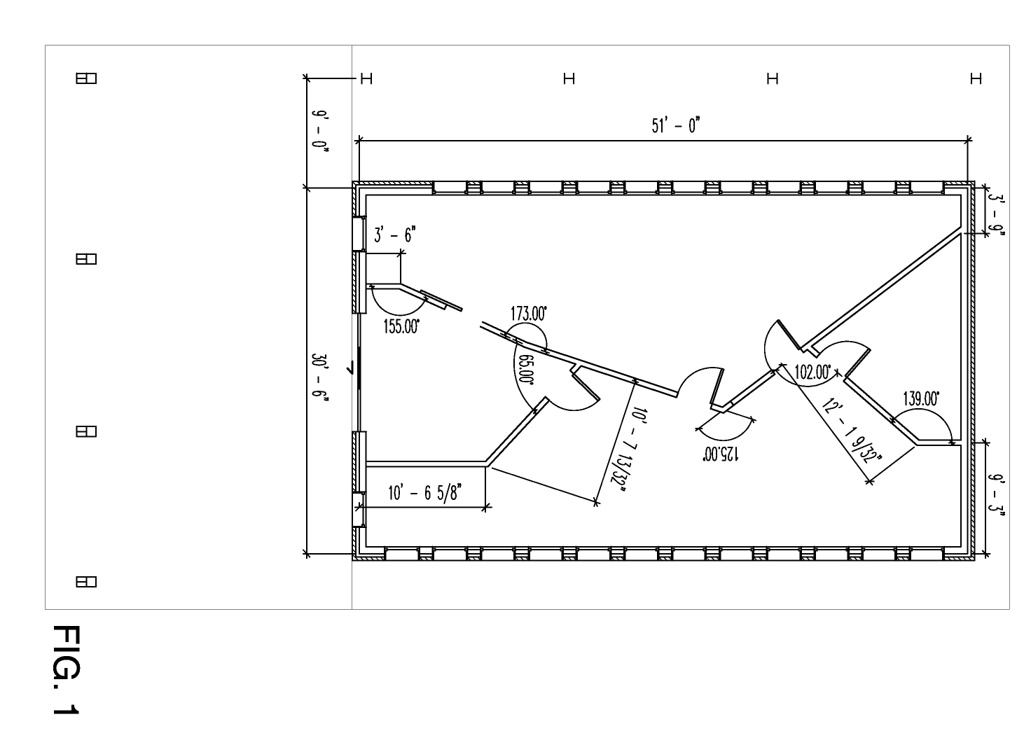

FIG. 1 is a representation of a digital image generated by a computer of a design plan. For example, in the architectural industry, architects typically generate two-dimensional floor plans to show what a building or structure looks like from above. The specific image shown in FIG. 1 is an example of what such a floor plan would look like on a computer screen. The invention described herein may apply to design plans, floor plan device designs, CAD drawings, vectored design plans, product drawings or other two-dimensional designs. These terms may be utilized interchangeably within this specification.

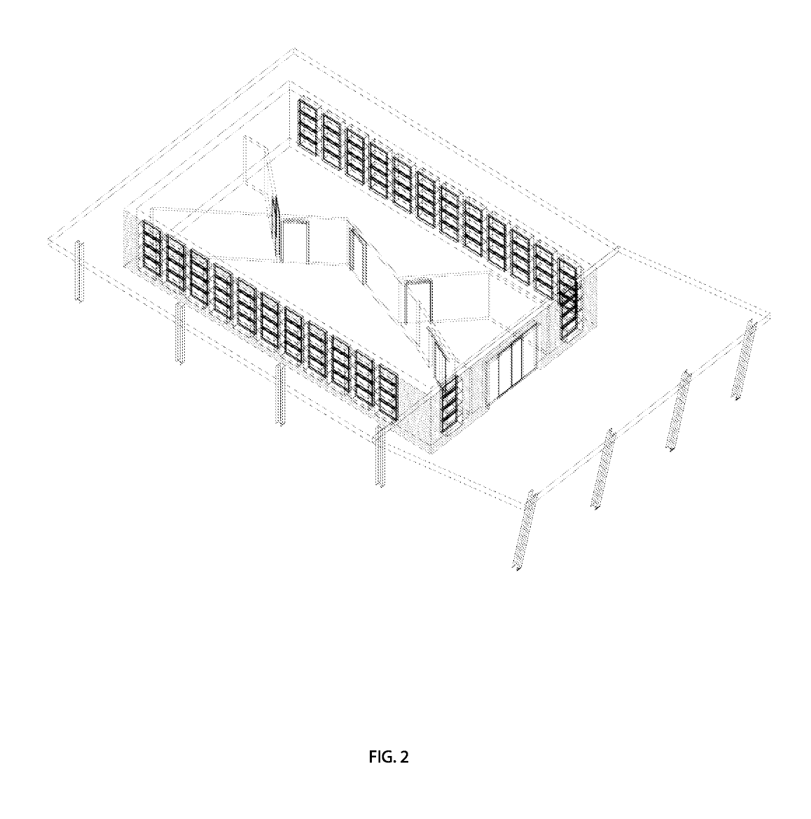

FIG. 2 is an illustration of an example of a three-dimensional computer model of the typical floor plan for a specific building. Upon completion of the model development, in an embodiment, an embedded software application within the drafting software may be deployed to create the augmentation marker and setup of the model, as well as the linking of the special and unique marker for each design plan. A standalone software application may also create the augmentation marker, setup of the model, and linking of the special and unique marker for each design plan. A unique and different marker will be generated in connection with the creation of each design plan and corresponding 3D model. In other words, a unique and special marker will be generated in connection with each individual process (or special marker will be transformed into a unique and special marker in connection with each individual process).

FIG. 2 is a representation of a three-dimensional model of a building generated by a computer or computing device. In the architectural industry, three-dimensional models of a building or structure are used for a three-dimensional understanding of a building or structure. In architecture, a particular three-dimensional (3D) model of a building can be created with the use of a two-dimensional floor plan, similar to the plan shown in FIG. 1. Architects use three-dimensional models in combination with a related two-dimensional plan for enhanced or a more detailed understanding of a building or structure

Upon selection of file name and location of the directory document to be saved, unique marker shall be printed on plans which will be linked to the model. Once the marker has been attached to the document to be printed, the file and the model may be linked together, saved on the local or cloud directory with direct link to the handheld application. Upon activation of the handheld device and simply pointing the camera to the printed marker, a computing device application may establish a link to the local or cloud directory and the specific model, and the enhanced or augmented image shall appear onto the handheld computing device. A computing device may be a mobile device (e.g., phone), tablet, laptop computer, desktop computer, network computer and in some embodiments, the terms may be utilized interchangeably. In an embodiment, the computing device may be a server, router, switch, or other similar devices, and those terms may also be utilized interchangeably.

In an embodiment, the marker may automatically generated using software or an application that enables the user to create and save the digital image in a unique file format (which may be referred to as the “Augmented Reality (AR) Enabling Application”). In an embodiment, this functionality may be incorporated in existing software, such as Autodesk Revit or AutoCad developed by Autodesk, Inc. and the digital image may be saved as a digital image in this file format utilizing the AR Enabling Application)

The image is associated with a unique marker that in turn is associated with augmented reality content (such as the three-dimensional model depicted in FIG. 2). The user is able to print a hard copy of the two-dimensional image with the designated marker for use by anyone who has a need to review and understand the information on the enhanced image. In creating a file using the above-described format, the user may want to designate a reference point on the digital image containing the marker that is associated with a corresponding reference point on the augmented reality. In an embodiment of the invention, this may be referred to as a tracker. This may be useful for the purpose of identifying a particular orientation for the augmented reality image or content to be viewed in conjunction with the enabling image.

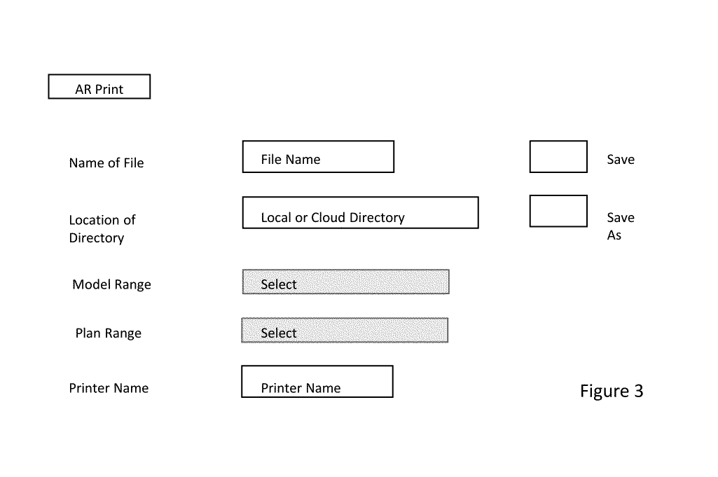

FIG. 3 is an illustration of an example of a print dialog box incorporating print and save process. In an embodiment, such as the example illustrated in FIG. 3, a selection of a name and location director for the document is made. If hard copy output is utilized, the application may cause instructions to be executed, and a unique marker may be printed on design drawings/drawing plans linked to the three dimensional model. After the marker has been attached to the document to be printed, the file and the model may be linked together, saved on the local or cloud directory, for later retrieval by the application on the handheld device. In an embodiment, upon activation of the application on the handheld device and pointing of the camera on the handheld device to the printed marker, the handheld device application may read, scan or capture the marker and/or link and establish a link to the selected local or cloud directory and retrieve the specific 3D model augmented reality or enhanced image file. The 3D model augmented reality or enhanced image file will appear on a display of the handheld device after being loaded into the local memory of the device.

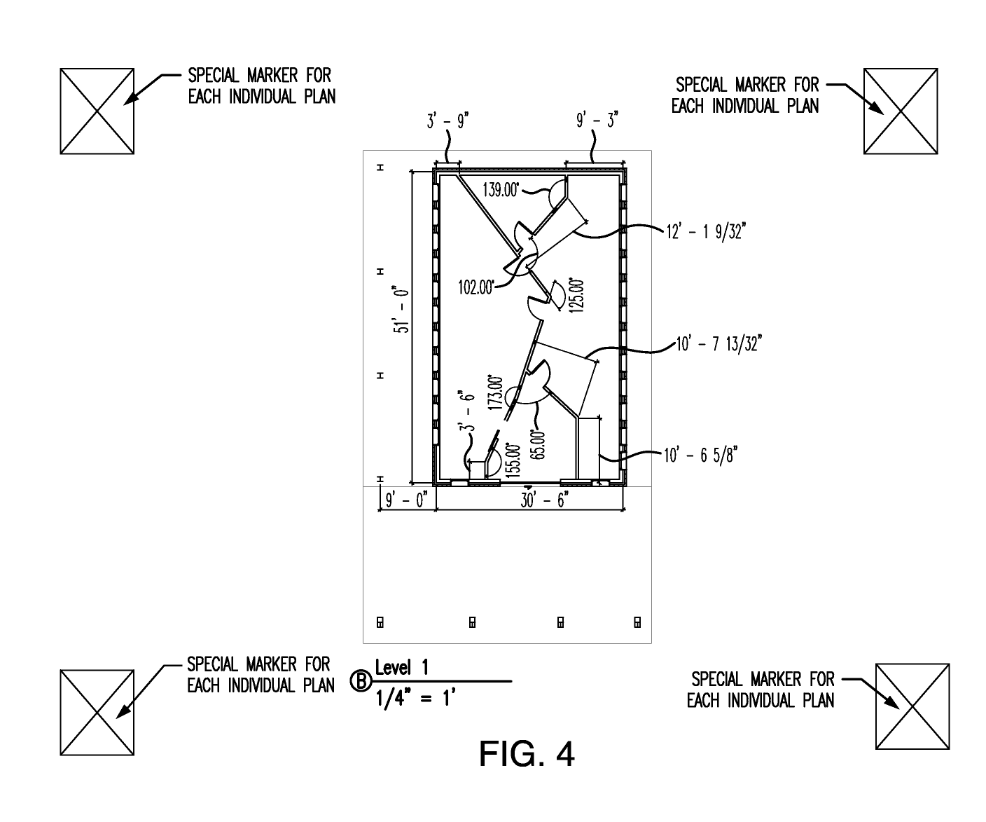

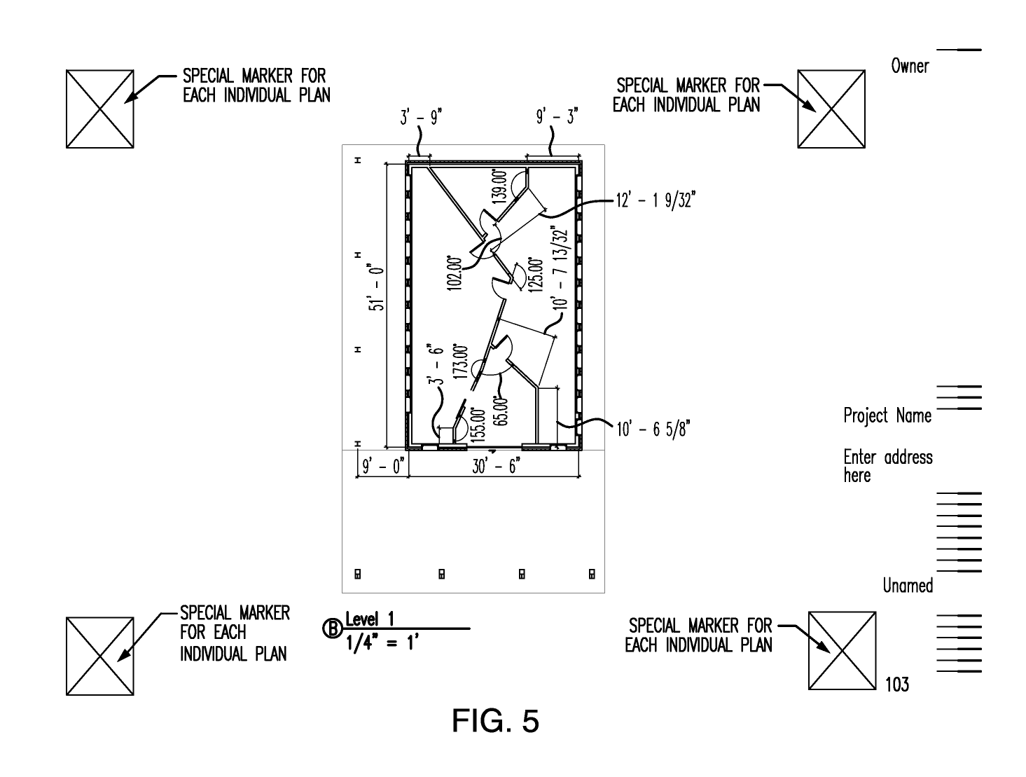

FIG. 4 is an illustration of an example of the floor plan of the building that is printed with the special marker which will be linked to a specific 3D model. In an embodiment, this process may occur within existing software products such as Autodesk Revit or AutoCad developed by Autodesk, Inc. FIG. 4 depicts a digital (or electronic) copy of such floor plan. FIG. 5 is the illustration of an example of the printed hard copy of the drawn plan (which contains the special marker). When hard copy is printed at any scale or print size, the invention of the special marker shall be shown or viewable on the hard copy. This special marker may also be embedded in an electronic document and/or viewable on an electronic document corresponding to a floor plan.

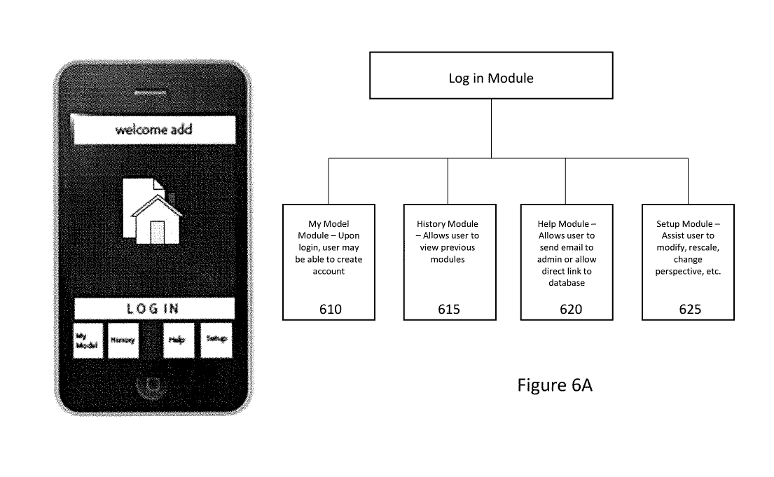

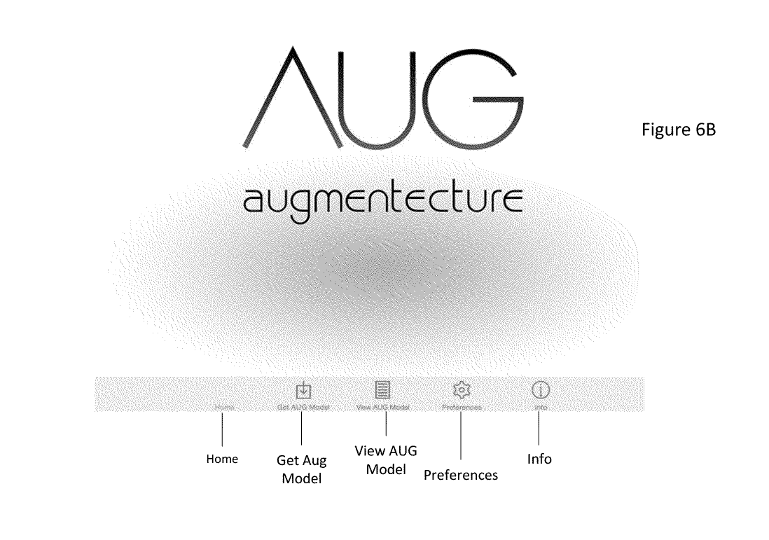

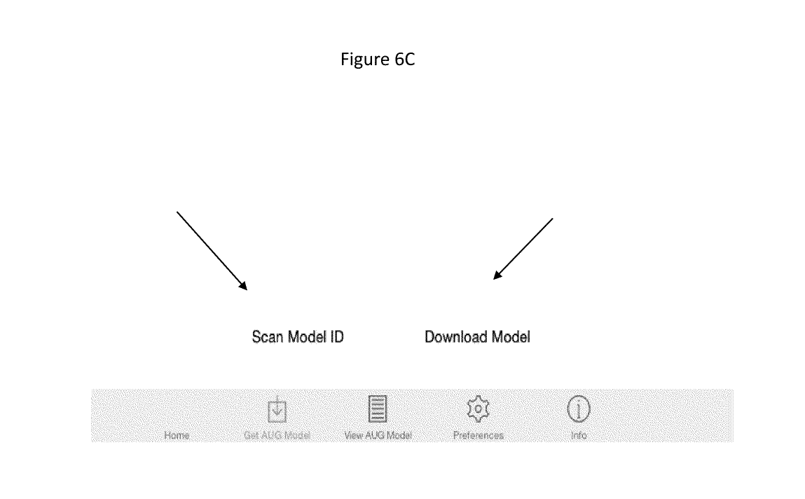

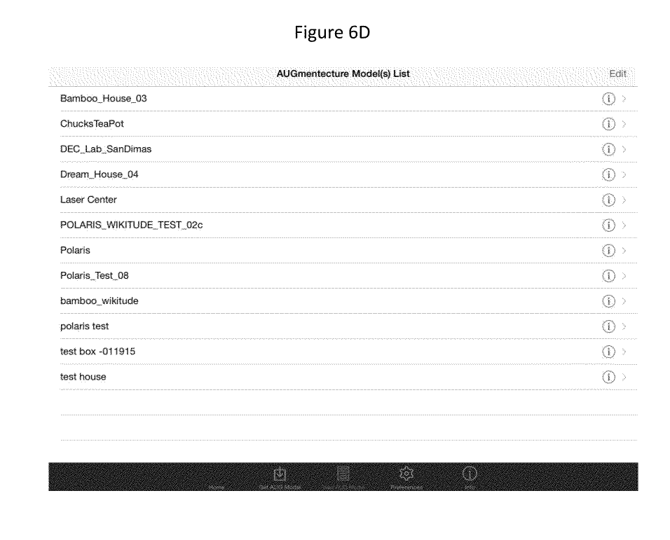

FIG. 6 is an illustration of an example screenshot of the hand held application and a block diagram of modules within the central server. The data flow below illustrates the different options available off the initial menu. FIG. 6 depicts a screen shot of the “log-in” page of an AR Browser Application according to an embodiment. A person intending to view the augmented reality content associated with the image depicted in FIG. 6 may be required to log into the AR Browser Application with appropriate user information via a login module to gain access to the content. A person running the AR Browser Application on his or her computer or mobile computing device may be able to view any particular augmented reality content only if the user enters the required information (if any) for gaining access to the account or file containing the augmented reality content. A user of the AR Enabling Application may restrict access to particular content or grant access to all augmented reality content generated by the user. Upon account creation, the AR Brower application may execute/initiate a My Model module 610. In the My Model module, the user may enter in information establishing the account in the AR Browser application. In an embodiment, a user may want to view past 3D model augmented reality or enhanced image files that were selected via the handheld computing device. The user may initiate or request execution of the History module 615, which provides users access to previously viewed 3D model AR or enhanced image files. In an embodiment, a user may request help from a system administrator or other user of the system by initiating the Help module 620. In the Help module, a user may also have direct linkage to the database housed in the central server. In an embodiment, the user may want to modify aspects or attributes of the 3D model augmented reality or enhanced image. The user may initiate the Setup module 625 to assist the user in modifying, rescaling, changing perspective, and/or adding in additional augmented reality features.

FIGS. 6B-6D illustrate screen shots of the mobile device software application including augmented reality features. A person intending to view the augmented reality content may be required to log into the mobile device augmented reality software application with appropriate user information via a login module to gain access to the content. A person running the application on his or her mobile computing device may be able to view any particular augmented reality content only if the user enters the required information (if any) for gaining access to the account or file containing the augmented reality content. FIG. 6B illustrates a main screen of the augmented reality software application according to an embodiment. A user may select from different options including “Home,” “Get AUG Model,” “View AUG Model,” “Preferences,” and “Info.” After initiating the augmented reality software application on his or her mobile device, a user may select to “Get AUG model” from the main menu shown in FIG. 6B. In an embodiment, if “Get AUG model” is selected, the augmented reality software application may display a menu such as FIG. 6C, which has options including “Scan Model ID” or “Download Model.” FIG. 6C is an illustration of a screen where marker capture and augmented reality image download functions are initiated. If a user selects “Scan Model ID,” the augmented software application activates or turns on the image capture device (e.g., camera or scanner”) which captures the scannable marker (or unique link) from the design plan if the user places the image capture device over the design plan and brings the scannable marker within view. The augmented reality software application uses the scannable marker (or unique link) to retrieve the augmented reality image file from a central server. In an embodiment, the augmented reality software application may then return to FIG. 6C. The user may then select “Download Model” in FIG. 6C and the augmented reality software application may download the augmented reality image file into the memory of the mobile computing device for display to the user. Returning to the main menu displayed in FIG. 6B, the user may select “View AUG Model” to view all of the models that have been downloaded to the mobile device and/or that are available for downloading to the mobile computing device. FIG. 6D illustrates a screen shot of what is displayed if the user selects “VIEW AUG Model.” In this embodiment, the user can select any one of the models in FIG. 6D and the augmented reality image file corresponding to the model may be displayed and/or downloaded. In an embodiment, a user may request help from a system administrator or other user of the system by selecting the “Info” button from the main menu in FIG. 6B. In the Info module, a user may also have direct linkage to the database housed in the central server. In an embodiment, the user may want to modify aspects or attributes of the 3D model augmented reality or enhanced image. The user may initiate the Preferences module by selecting the “Preferences” button in FIG. 6B to assist the user in modifying, rescaling, changing perspective, and/or adding in additional augmented reality features.

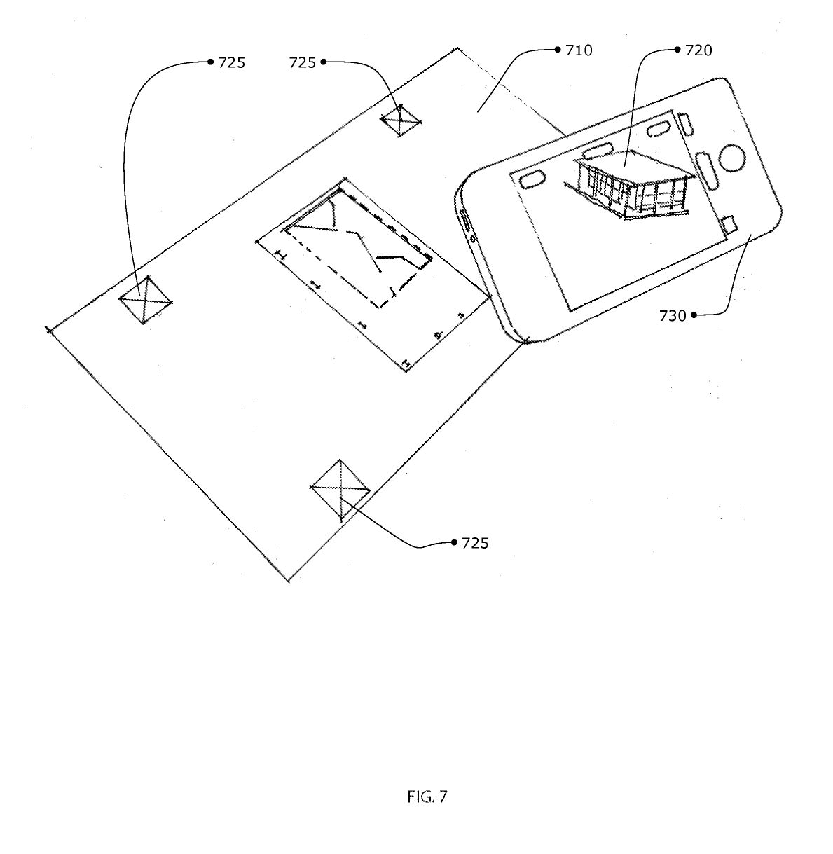

FIG. 7 is the illustration of an example of the application deployed and used to view model of the specific plan by the hand held device. FIG. 7 depicts an image of a mobile computing device that is used to view augmented reality content associated with the unique marker printed on the hard copy of the digital image depicted in FIG. 1. As illustrated in FIG. 7, the design plan is represented by reference number 710. The augmented reality content or enhanced image file 720 is viewable on the mobile computing device by bringing the marker 725 (on the printout of the image depicted in FIG. 1) within the field of view of the mobile device 730.

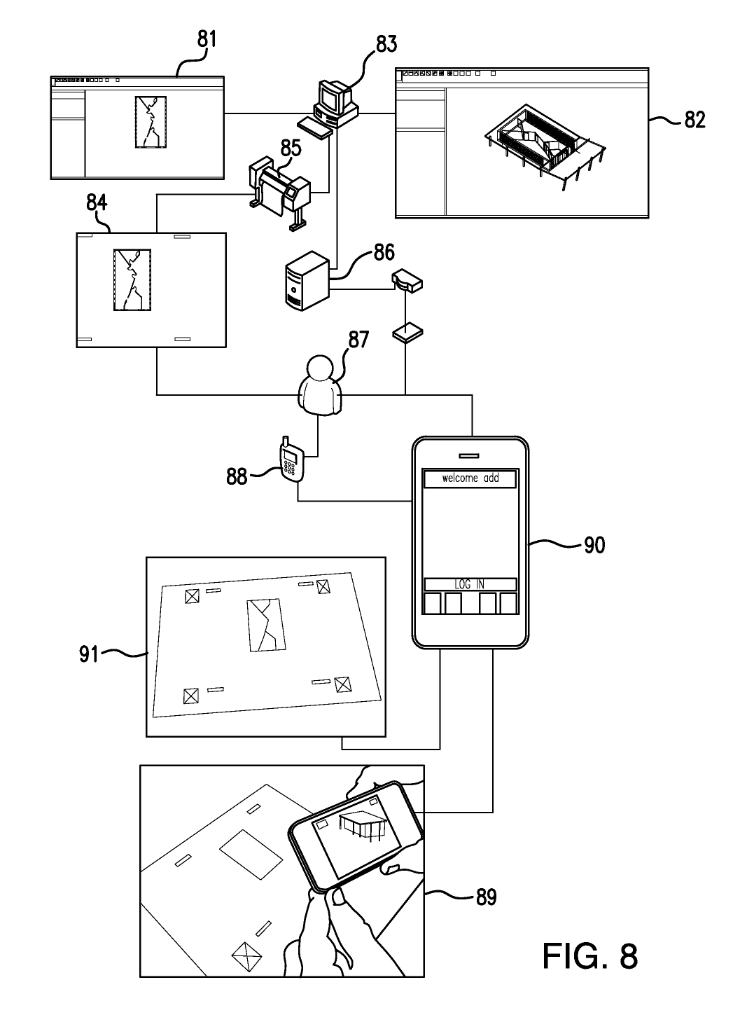

FIG. 8 is a diagram showing the entire system and process for creating and using augmented reality content. Reference Number 81 (which corresponds with FIG. 1) is a representation of a digital image generated by a computer for a design plan or design drawing. In the architectural industry, the design plan may be a two-dimensional floor plan. Architects typically generate two-dimensional floor plans to show what a building or structure looks like from above. The specific image shown in Reference Number 81 is an example of what such a floor plan would look like on a computer screen.

Reference Number 82 (which corresponds with FIG. 2) is a representation of a three-dimensional model of a building generated by a computer. In the architectural industry, three-dimensional models of a building or structure are used for a three-dimensional understanding of a building or structure. In architecture, a particular three-dimensional model of a building can be created with the use of a two-dimensional floor plan, similar to the plan shown in Reference Number 81. Architect use three-dimensional models in combination with a related two-dimensional plan for enhanced or a more detailed understanding of a building or structure.

Reference Number 83 is a representation of a computer or computing device that is used to generate the digital images depicted in Reference Numbers 81 and 82. The computer or computing device is in turn used to create a version of the digital image represented in FIG. 1 (or 81) that contains a unique marker or link used to associate the digital image in FIG. 1 (or 81) with the three-dimensional model represented in FIG. 2 (or 82). In an embodiment, the digital image may also comprise a second marker/tracker to orient the 3D model augmented reality or enhanced image file. As an illustrative example, an image containing the special marker is depicted in FIG. 4. In an embodiment, the printed hard copy of such digital image containing the special marker is depicted in Reference Number 84.

Reference Number 83 is a representation of a computer or computing device that is used to generate the digital images depicted in reference numbers 81 and 82. The computer or computing device is in turn used to create a version of the digital image represented in FIG. 1 (or 81) that contains a unique marker used to associate the digital image in FIG. 1 (or 81) with the three-dimensional model represented in FIG. 2 (or 82). This digital image containing the special marker is depicted in FIG. 4. The printed hard copy of such digital image containing the special marker is depicted in Reference Number 84.

The marker is automatically generated using software or an application that enables the user to create and save the digital image in a unique file format (the “AR Enabling Application”). This functionality may be incorporated in existing software, such as Autodesk Revit or AutoCad developed by Autodesk, Inc. By saving the digital image in this file format (through the AR Enabling Application) the digital image (or 3D augmented reality or enhanced image file) is associated with a unique marker that in turn is associated with augmented reality content (such as the three- dimensional model depicted Reference Number 89 (which corresponds with FIG. 7)), as described below. The user is able to print a hard copy of the two-dimensional image with the designated marker (which hard copy is depicted in FIG. 4 or 84 (referenced below)) for use by anyone who has a need to review and understand the information on the image. In an embodiment, the user may be able to generate an electronic document which includes the designated marker viewable therein. In creating a file using the above-described format, the user may want to designate a reference point on the digital image containing the marker that is associated with a corresponding reference point on the augmented reality. This may be referred to as a tracker. This may be useful for the purpose of identifying a particular orientation for the augmented reality image or content to be viewed in conjunction with digital image (or 3D model augmented reality or enhanced image file).

Reference Number 85 depicts a printer that can be used to print a hard copy of the image containing the unique marker generated using the above-described software application. Alternatively, the software application will enable the user to “print” a soft (or electronic) copy of the digital image in FIG. 1 (or 81) with the unique marker by enabling the user to save the digital image in a unique file format. This process is analogous to the process of creating an electronic copy of a document in Portable Document Format (PDF), (i.e., an Adobe Acrobat product output). In an embodiment, the digital image in FIG. 1 (or 81) is created by converting the base document to a special file format that contains a unique marker associated with augmented reality content viewable through the use of an augmented reality browser or platform, such as the browsers developed by Aurasma and Wikitude. The special file format may be the .AUG file format and may also include a second marker or tracker for orientating the image.

The special file format may be referred to as the .AUG format. The .AUG format may be a standard format so that when all design plans, design drawings, CAD documents, product designs, are converted to .AUG, the documents look just like they would if printed. When a .AUG file is shared, anyone with a Augmented Reality browser may read it using free software or a mobile application browser from a different source.

Reference Number 86 depicts a central server on which a soft (or electronic) copy of the digital image depicted in 89 is stored, along with information as to the unique marker(s) with which the image is associated. In other words, the digital image corresponding to the three dimensional model is stored along with a reference key (i.e., the unique marker) and/or the second marker/tracker, for later retrieval. The central server may be connected to mobile devices or other computing devices via a network, whether it is a wired network or a wireless communication network.

Reference Number 87 depicts an individual user of a handheld or mobile device (or other computing device) that is running an application enabling viewing of augmented reality content on the computer or mobile device (“AR Browser Application”). This is achieved by bringing the digital image containing the marker within the field of view of the handheld or mobile device (more specifically, within the field of view of the optical viewing apparatus, camera, or scanner of such device). In an embodiment, the AR Browser application may be downloadable or may have a downloadable component (it could be a plug in to another application) to enable. For purposes of clarity, the AR Browser Application is a distinct and different from the AR Enabling Application that is used on the computer or computing device 83. The AR Browser Application is downloaded or used on the above-referenced handheld or mobile device (or other mobile computing device including but not limited to tables).

Reference Number 88 depicts a mobile computing device that used to view augmented reality content associated with the unique marker printed on the hard copy of the digital image depicted in FIG. 1. Reference Number 90 depicts a screen shot of the “log-in” page of the AR Browser Application that is accessed using the mobile computing device. A person intending to view the augmented reality content associated with the image depicted in FIG. 1 (or 81) may be required to log into the AR Browser Application with appropriate user information to gain access to the content. A person running the AR Browser Application on his or her computer or mobile computing device would be able to view any particular augmented reality content only if the user enters the required information (if any) for gaining access to the account or file containing the augmented reality content. A user of the AR Enabling Application may restrict access to particular content or grant access to all augmented reality content generated by the user. Initially, the user will log in to the AR Browser Application on the mobile computing device 88 which will communicate with the central server 86. The user will then locate the two dimensional plan 91 that was printed with special markers. The augmented reality content is viewable on the mobile computing device by bringing the marker (on the printout of the image depicted in FIG. 1 (or 81)) within the field of view of the mobile device. In this case, a reader on the mobile communication device (or a software image capture program) on the mobile communication device will recognize (or capture and process the marker) and then send the recognized or captured special marker data to the central server. The central server 86 may retrieve the image file representing the three dimensional model that corresponds with the architectural plan (along with associated data such as additional augmented reality. information and special marker data) and will transmit this to the mobile communication device 88. The mobile communication device 88 may display the image file representing the three dimensional model corresponding to the two dimensional plan which was printed with the special marker, as shown in 89. The mobile communication device may also display any additional augmented reality data corresponding to the two-dimensional plan.

Reference Number 90 depicts a screen shot of the AR Browser Application enabling the user to place notes or comments with respect to the augmented reality content that the user would be able to view by using the AR Browser Application. The AR Browser Application may be used to make changes or edits to the augmented reality content. Any changes or revised versions of the augmented reality content may be saved as a new file. The revised version of the augmented reality content would be stored on the central server 86 containing the images. A computer-generated message is sent to users with access to the user of the AR Enabling Application to notify the user as to any changes or edits to the augmented reality content.

Reference Number 91 depicts a hard copy of the drawn plan containing a special or unique marker that is used for linking the drawn plan to corresponding augmented content (in particular, a corresponding three dimensional model) that can be viewed by bringing the special marker within the field of view of the handheld or mobile

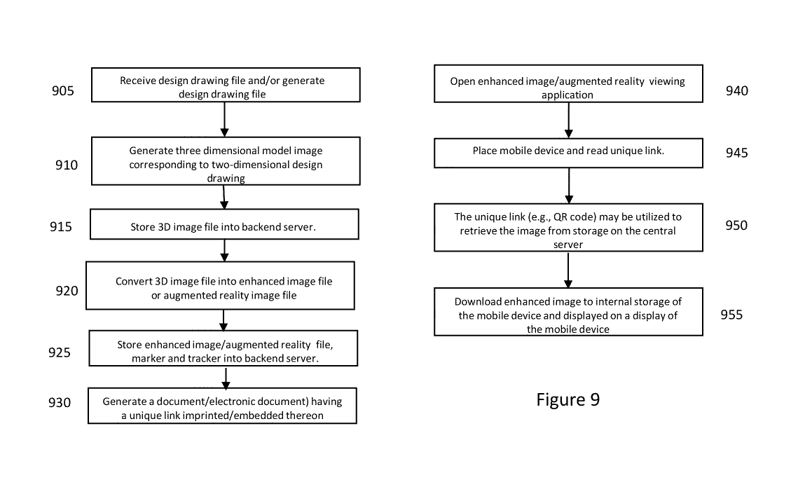

FIG. 9 is a flowchart 900 detailing a method of generating an enhanced image file in accordance with an embodiment. The enhanced image file may include augmented reality features. The method begins at 905 with the computing device receiving a design drawing file. In an embodiment, the design drawing file may be an architectural drawing, a product drawing, a structural drawing, or any two-dimensional drawing representing a three-dimensional object. In an embodiment, the computing device may be able to generate the design drawing file utilizing design (CAD, architectural, etc.) software. At 910, a three-dimensional (3D) model image file may be received from the computing device. In an embodiment, the 3D model image file may be generated based on the design drawing file. In other words, the 3D model image corresponds to or is associated with the design drawing file. A number of commercially available software programs may generate the 3D model image file such as Revit from Autodesk.

Mobile computing devices may be, but are not limited to tablets, smartphones, mobile phones, portable computers, and other similar devices. At 915, in an embodiment, the 3D model image file may be exported and stored at a central server. In an illustrative embodiment, the central server may be a backend cloud system. In an embodiment, the 3D model image file may be stored in the backend cloud-based system. In the backend cloud-based system, the central server may strip off layers and/or may reduce polygon counts to compress the 3D model image file to a smaller size. In an embodiment of the invention, the 3D model image file may then be converted into a FBX format (which is a Filmbox format) or other formats.

At 920, in an embodiment, the 3D model image (or 3D model image in FBX format, which is a Filmbox format) may be converted into an enhanced image file or an augmented reality image file. The enhanced image file format may be referred to as an .AUG file format. The enhanced image file may include augmented reality features and/or content in addition to the 3D model image. In an embodiment, a unique link (or URL) may be assigned to the enhanced image file. In an embodiment, the unique link may include a first marker and a second marker. The first marker may be a scannable or encoded marker. The first marker may be a unique identifier that identifies the enhanced image file. The second marker may be a tracker and used for tracking purposes. The second marker may be used to orient the image on the two-dimensional print output as well as in a viewable image. In an embodiment, the first marker and/or the second marker may be assigned and/or correspond to the enhanced image file, which may also be referred to as the augmented reality file.

At 925, the enhanced image file, first marker (e.g., scannable/readable marker), and second marker/tracker may be stored on the central server (e.g., the backend cloud-based server). In an illustrative embodiment, the enhanced image file, first marker, and second marker may be stored in a single file. In other embodiments, the enhanced image file, first marker and second marker may be stored in separate, but linked files. In an embodiment, the enhanced image file may include augmented reality features or content. In this specification, the enhanced image file may be interchangeably referred to as the augmented reality file.

At 930, in an embodiment, the backend server (or another computing device) may generate a document (or electronic document) having a unique link (e.g., first marker and second marker) either imprinted thereon or embedded thereon. In other words, if the electronic document is viewed, rather than printed, a unique link (e.g., first marker or scannable and/or a second marker or tracker) may be visible within the viewed electronic document.

In an embodiment, an uploader program may be utilized to load the enhanced image or augmented reality file, first marker, and second maker into the backend server. In this illustrative embodiment, the designer or creator who would develop a design of some kind may store the enhanced imaged file in the back end server in an assigned and password protected workspace. In an embodiment, from the protected workspace, the designer or creator of the design may print the document (or view electronic document) associated with the design drawing file including the first marker and/or the second marker printed thereon (or having the first marker and/or the second marker viewable in the electronic document). In an embodiment of the invention, the central server or central computing device may house a database application server as well an application server. In an illustrative embodiment, the database application server and/or the application server may be housed on virtual servers hosted securely by third parties. For example, the remote housing/hosting may be referred to as a multitenant database application and the overall design may be referred to as multi-tenancy software architecture and design. In this embodiment, each user may have a dedicated account with his or her own or the organization's own profile settings. As part of the multitenant software application and for security and privacy measures the models image files, first markers, second markers and any related information may be stored in non-shared database tables and will be maintained properly and will be backed up regularly as part of our maintenance process. In an embodiment, each user will be given a certain amount of storage space upon initial sign up and additional storage spaces will be granted upon request and some nominal fees.

At 940, a viewing software application (e.g., an AUGmentecture application) may be opened on a mobile computing device, which may be a mobile phone, smart phone, tablet, portable computer, or other similar devices. In an embodiment, the viewing software application may only present the enhanced image file which may be viewed over a hard copy of the design drawing file. In another embodiment, the viewing software application may present the enhanced image file which may be presented over an electronic image of the design drawing file.

At 945, after opening the software application, the mobile device may be placed over the printed document (or viewable document), and specifically over the unique link (e.g., scannable marker), and may read, capture or scan the unique link. The mobile device may be a smart phone, a tablet, a mobile phone, a portable computer, or other similar devices.

At 950, the unique link (e.g., scannable marker) may be utilized to retrieve the image from storage on the central server. For example, a URL may be encoded in the scannable marker and may provide an address where the enhanced image file is located. In an embodiment, the software application may open a browser which may utilize the URL to locate the enhanced image file and retrieve the enhanced image file from the central server. In an embodiment, the enhanced image file may include augmented reality content.

At 955, the enhanced image file may be downloaded to internal storage of the mobile device and displayed on a display of the mobile device. In an embodiment, the 3D model may be viewed by pointing at the printed unique link in the printed design document or by pointing at the viewable unique link in the viewable electronic document.

Description of Creation of Unique Link or First Marker—In an embodiment, each time an enhanced image file (e.g., an .AUG image file), the server may generate a unique link comprising the first marker. In this embodiment, each enhanced image file may have its own unique link so there is no duplication. In this illustrative embodiment, the unique link may be utilized to generate embedded codes. In an embodiment, the backend server may generate a scannable code as the first marker to create a unique scannable code corresponding to the augmented file. This unique code may ensure that each project is uniquely databased and may have a reference.

Description of Creation of Second Marker/Tracker—In an embodiment, a third party application may create the second marker/tracker. In augmented reality software platforms, the second marker may be created using shapes and images that may represent a brand or a message. The augmented reality software platforms may have rules and requirements for generating the second marker/tracker. In an embodiment, the marker may be created by producing a 2D jpeg image. The images may be any size and/or shape as long as there is enough contrast for the tracking to occur. As an illustrative example, if the second marker/tracker is all grey or a single color without a number of darker or lighter shape, then the software application may not pick up or be able to read the second marker/tracker. In an embodiment, the second marker/tracker may be uploaded to a third party cloud-based application to test how well the marker is designed. In an embodiment of the invention, the second marker/tracker may be utilized by the software application and then downloaded for integration into the backend system. In an embodiment, the software application may be an augmented reality application and/or platform.

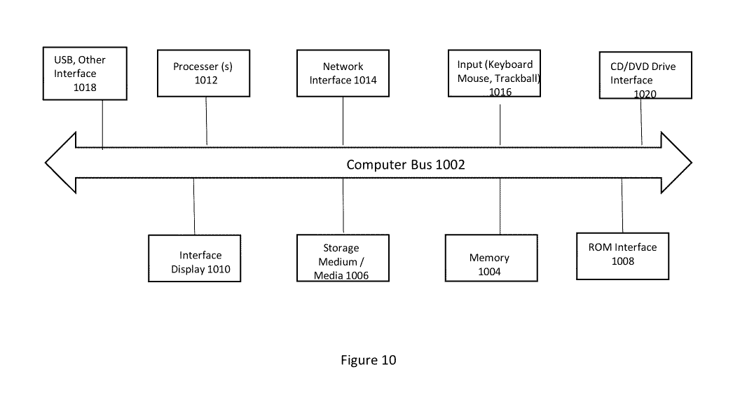

A computing device may be a server, a computer, a laptop computer, a mobile computing device, and/or a table. FIG. 10 illustrates a computing device according to an embodiment. As shown in the example of FIG. 10, internal architecture of a computing device 1000 includes one or more processers (also referred to herein as CPUs) 1012, which interface with at least one computer bus 1002. Also interfacing with computer bus 1002 are persistent storage medium/media 1006, network interface 1014, memory 1004, e.g., random access memory (RAM), run-time transient memory, read only memory (ROM), etc., media disk drive interface 1008, an interface 1020 for a drive that can read and/or write to media including removable media such as floppy, CD-ROM, DVD, etc., media, display interface 1010 as interface for a monitor or other display device, keyboard interface 1016 as interface for a keyboard, mouse, trackball and/or pointing device, and other interfaces 1018 not shown individually, such as parallel and serial port interfaces, a universal serial bus (USB) interface, and the like.

Memory 1004 interfaces with computer bus 1002 so as to provide information stored in memory 1004 to CPU 1012 during execution of software programs such as an operating system, application programs, device drivers, and software modules that comprise program code or logic, and/or computer-executable process steps, incorporating functionality described herein, e.g., one or more of process flows described herein. CPU 1012 first loads computer-executable process steps or logic from storage, e.g., memory 1004, storage medium/media 1006, removable media drive, and/or other storage device. CPU 1012 can then execute the stored process steps in order to execute the loaded computer-executable process steps. Stored data, e.g., data stored by a storage device, can be accessed by CPU 1012 during the execution of computer-executable process steps.

Persistent storage medium/media 1006 is a computer readable storage medium(s) that can be used to store software and data, e.g., an operating system and one or more application programs. Persistent storage medium/media 1006 can also be used to store device drivers, such as one or more of a digital camera driver, monitor driver, printer driver, scanner driver, or other device drivers, web pages, content files, metadata, playlists and other files. Persistent storage medium/media 1006 can further include program modules/program logic in accordance with embodiments described herein and data files used to implement one or more embodiments of the present disclosure.

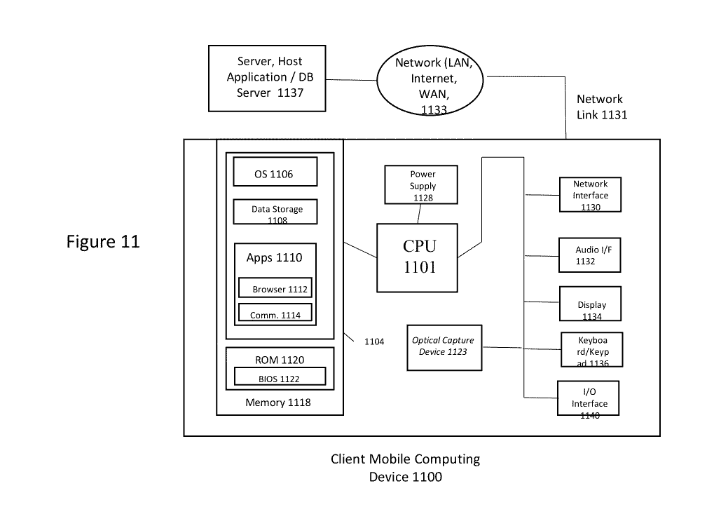

FIG. 11 is a schematic diagram illustrating a client device implementation of a computing device in accordance with embodiments of the present disclosure. A client device 1100 may include a computing device capable of sending or receiving signals, such as via a wired or a wireless network, and capable of running application software or “apps” 1110. In an embodiment, the client device 1100 may communicate with a central server computing device 1000, such as described above. A client device may, for example, include a desktop computer or a portable device, such as a cellular telephone, a smart phone, a display pager, a radio frequency (RF) device, an infrared (IR) device, a Personal Digital Assistant (PDA), a handheld computer, a tablet computer, a laptop computer, a set top box, a wearable computer, an integrated device combining various features, such as features of the forgoing devices, or the like.

A client device may vary in terms of capabilities or features. The client device can include standard components such as a CPU 1102, power supply 1128, a memory 1118, ROM 1120, BIOS 1122, network interface(s) 1130, audio interface 1132, display 1134, keyboard/keypad/pointing device 1136, I/O interface 1140 interconnected via buses, traces or circuitry 1126. In an embodiment, the client device may include an optical device 1123 (e.g., a camera, a scanner, or an optical reader device) to capture and/or scan links, codes, images, and the like. Claimed subject matter is intended to cover a wide range of potential variations. For example, the keyboard/keypad/pointing device/touchscreen 1136 of a cell phone may include input 1134 of limited functionality, such as a monochrome liquid crystal display (LCD) for displaying text. In contrast, however, as another example, a web-enabled client device 1100 may include one or more physical or virtual keyboards 1136, mass storage, or a display with a high degree of functionality, such as a touch-sensitive color 2D or 3D display, for example. The memory 1118 can include Random Access Memory 1104 including an area for data storage 1108.

A client device 1100 may include or may execute a variety of operating systems 1106, including a personal computer operating system, such as a Windows, iOS or Linux, or a mobile operating system, such as iOS, Android, or Windows Mobile, or the like. A client device 1100 may include or may execute a variety of possible applications 1110, such as a client software application 1114 enabling communication with other devices, such as communicating one or more messages such as via email, short message service (SMS), or multimedia message service (MMS), including via a network, such as a social network, including, for example, Facebook, LinkedIn, Twitter, Flickr, or Google+, to provide only a few possible examples. A client device 1100 may also include or execute an application to communicate content, such as, for example, textual content, multimedia content, or the like. A client device 1100 may also include or execute an application to perform a variety of possible tasks, such as browsing 1112, searching, playing various forms of content, including locally stored or streamed content. The foregoing is provided to illustrate that claimed subject matter is intended to include a wide range of possible features or capabilities. The client computing device or mobile computing device 1100 may also include imaging software applications for capturing, processing, modifying and transmitting image files utilizing the optical device (e.g., camera, scanner, optical reader) within the mobile computing device.

Network link 1131 typically provides information communication using transmission media through one or more networks to other devices that use or process the information. For example, network link 1131 may provide a connection through a network (LAN, WAN, Internet, packet-based or circuit-switched network) 1133 to a sever 1137, which may be operated by a third party housing and/or hosting service. For example, the server 1137 may be the server described in detail above. The server 1137 hosts a process that provides services in response to information received over the network 1133, for example, like application, database or storage services. It is contemplated that the components of system can be deployed in various configurations within other computer systems, e.g., host and server.

For the purposes of this disclosure a computer readable medium stores computer data, which data can include computer program code that is executable by a computer, in machine readable form. By way of example, and not limitation, a computer readable medium may comprise computer readable storage media, for tangible or fixed storage of data, or communication media for transient interpretation of code-containing signals. Computer readable storage media, as used herein, refers to physical or tangible storage (as opposed to signals) and includes without limitation volatile and non-volatile, removable and non-removable media implemented in any method or technology for the tangible storage of information such as computer-readable instructions, data structures, program modules or other data. Computer readable storage media includes, but is not limited to, RAM, ROM, EPROM, EEPROM, flash memory or other solid state memory technology, CD-ROM, DVD, or other optical storage, magnetic cassettes, magnetic tape, magnetic disk storage or other magnetic storage devices, or any other physical or material medium which can be used to tangibly store the desired information or data or instructions and which can be accessed by a computer or processor.

For the purposes of this disclosure a system or module is a software, hardware, or firmware (or combinations thereof), process or functionality, or component thereof, that performs or facilitates the processes, features, and/or functions described herein (with or without human interaction or augmentation). A module can include sub-modules. Software components of a module may be stored on a computer readable medium. Modules may be integral to one or more servers, or be loaded and executed by one or more servers. One or more modules may be grouped into an engine or an application.

Those skilled in the art will recognize that the methods and systems of the present disclosure may be implemented in many manners and as such are not to be limited by the foregoing exemplary embodiments and examples. In other words, functional elements being performed by single or multiple components, in various combinations of hardware and software or firmware, and individual functions, may be distributed among software applications at either the client or server or both. In this regard, any number of the features of the different embodiments described herein may be combined into single or multiple embodiments, and alternate embodiments having fewer than, or more than, all of the features described herein are possible. Functionality may also be, in whole or in part, distributed among multiple components, in manners now known or to become known. Thus, myriad software/hardware/firmware combinations are possible in achieving the functions, features, interfaces and preferences described herein. Moreover, the scope of the present disclosure covers conventionally known manners for carrying out the described features and functions and interfaces, as well as those variations and modifications that may be made to the hardware or software or firmware components described herein as would be understood by those skilled in the art now and hereafter.

Regarding aspects related to a communications and/or computing network, a wireless network may couple client devices with a network. A wireless network may employ stand-alone ad-hoc networks, mesh networks, Wireless LAN (WLAN) networks, cellular networks, and/or the like. A wireless network may further include a system of terminals, gateways, routers, and/or the like coupled by wireless radio links, and/or the like, which may move freely, randomly and/or organize themselves arbitrarily, such that network topology may change, at times even rapidly. A wireless network may further employ a plurality of network access technologies, including Long Term Evolution (LTE), WLAN, Wireless Router (WR) mesh, 2nd, 3rd, or 4th generation (2G, 3G, or 4G) cellular technology and/or the like. Network access technologies may enable wide area coverage for devices, such as client devices with varying degrees of mobility, for example.

A network may enable radio frequency and/or other wireless type communications via a wireless network access technology and/or air interface, such as Global System for Mobile communication (GSM), Universal Mobile Telecommunications System (UMTS), General Packet Radio Services (GPRS), Enhanced Data GSM Environment (EDGE), 3GPP Long Term Evolution (LTE), LTE Advanced, Wideband Code Division Multiple Access (WCDMA), Bluetooth, ultra wideband (UWB), 802.11b/g/n, and/or the like. A wireless network may include virtually any type of now known and/or to be developed wireless communication mechanism by which signals may be communicated between devices, between networks, within a network, and/or the like.

Communications between a computing device and/or a network device and a wireless network may be in accordance with known and/or to be developed communication network protocols including, for example, global system for mobile communications (GSM), enhanced data rate for GSM evolution (EDGE), 802.11 b/g/n, and/or worldwide interoperability for microwave access (WiMAX). A computing device and/or a networking device may also have a subscriber identity module (SIM) card, which, for example, may comprise a detachable smart card that is able to store subscription content of a user, and/or is also able to store a contact list of the user. A user may own the computing device and/or networking device or may otherwise be a user, such as a primary user, for example. A computing device may be assigned an address by a wireless network operator, a wired network operator, and/or an Internet Service Provider (ISP). For example, an address may comprise a domestic or international telephone number, an Internet Protocol (IP) address, and/or one or more other identifiers. In other embodiments, a communication network may be embodied as a wired network, wireless network, or any combinations thereof.

Algorithmic descriptions and/or symbolic representations are examples of techniques used by those of ordinary skill in the signal processing and/or related arts to convey the substance of their work to others skilled in the art. An algorithm is here, and generally, is considered to be a self-consistent sequence of operations and/or similar signal processing leading to a desired result. In this context, operations and/or processing involve physical manipulation of physical quantities. Typically, although not necessarily, such quantities may take the form of electrical and/or magnetic signals and/or states capable of being stored, transferred, combined, compared, processed or otherwise manipulated as electronic signals and/or states representing various forms of content, such as signal measurements, text, images, video, audio, etc. It has proven convenient at times, principally for reasons of common usage, to refer to such physical signals and/or physical states as bits, values, elements, symbols, characters, terms, numbers, numerals, measurements, content and/or the like. It should be understood, however, that all of these and/or similar terms are to be associated with appropriate physical quantities and are merely convenient labels. Unless specifically stated otherwise, as apparent from the preceding discussion, it is appreciated that throughout this specification discussions utilizing terms such as “processing,” “computing,” “calculating,” “determining”, “establishing”, “obtaining”, “identifying”, “selecting”, “generating”, and/or the like may refer to actions and/or processes of a specific apparatus, such as a special purpose computer and/or a similar special purpose computing and/or network device. In the context of this specification, therefore, a special purpose computer and/or a similar special purpose computing and/or network device is capable of processing, manipulating and/or transforming signals and/or states, typically represented as physical electronic and/or magnetic quantities within memories, registers, and/or other storage devices, transmission devices, and/or display devices of the special purpose computer and/or similar special purpose computing and/or network device. In the context of this particular patent application, as mentioned, the term “specific apparatus” may include a general purpose computing and/or network device, such as a general purpose computer, once it is programmed to perform particular functions pursuant to instructions from program software.

In some circumstances, operation of a memory device, such as a change in state from a binary one to a binary zero or vice-versa, for example, may comprise a transformation, such as a physical transformation. With particular types of memory devices, such a physical transformation may comprise a physical transformation of an article to a different state or thing. For example, but without limitation, for some types of memory devices, a change in state may involve an accumulation and/or storage of charge or a release of stored charge. Likewise, in other memory devices, a change of state may comprise a physical change, such as a transformation in magnetic orientation and/or a physical change and/or transformation in molecular structure, such as from crystalline to amorphous or vice-versa. In still other memory devices, a change in physical state may involve quantum mechanical phenomena, such as, superposition, entanglement, and/or the like, which may involve quantum bits (qubits), for example. The foregoing is not intended to be an exhaustive list of all examples in which a change in state form a binary one to a binary zero or vice-versa in a memory device may comprise a transformation, such as a physical transformation. Rather, the foregoing is intended as illustrative examples.

In the preceding description, various aspects of claimed subject matter have been described. For purposes of explanation, specifics, such as amounts, systems and/or configurations, as examples, were set forth. In other instances, well-known features were omitted and/or simplified so as not to obscure claimed subject matter. While certain features have been illustrated and/or described herein, many modifications, substitutions, changes and/or equivalents will now occur to those skilled in the art. It is, therefore, to be understood that the appended claims are intended to cover all modifications and/or changes as fall within claimed subject matter.

1. A computer-implemented method comprising:
receiving, a computing device, a design file of a structure;
receiving, at the computing device, an image file representing a three-dimensional (3D) model of the structure;
generating, at the computing device, an augmented reality file representing the two-dimensional design file, the augmented reality file linked to a marker uniquely identifying a location of the augmented reality file; and
generating, at the computing device, a copy of the design file, the copy including the marker.

2. The computer-implemented method of claim 1, wherein generating a copy further comprises generating, at a printer, a printed copy of the design file, the marker being printed on the printed copy.

3. The computer-implemented method of claim 1, wherein generating a copy further comprises generating, at the computing device, an electronic document representing the design file, the marker being visible within the electronic document.

4. The computer-implemented method of claim 1, the augmented reality file being further linked to a reference point, the reference point to identify a particular viewing orientation for the image file representing the 3D model of the structure.

5. The computer-implemented method of claim 2, further comprising transmitting the augmented reality file to a central server.

6. The computer-implemented method of claim 1, the marker further comprising a link to the augmented reality file, the link being utilized to retrieve the second file from the central server.

7. The computer-implemented method of claim 1, wherein the structure is a building, the design file representing a floor plan and the 3D model is a 3D model of a building.

8. A computer-implemented method, comprising:
capturing, at a computing device, a generated marker, the generated marked being printed on a design document, or viewable on an electronic document representing the design document;
utilizing, at the computing device, the generated marker, to connect to central server, and link to a an augmented reality file corresponding to a three-dimensional (3D) model associated with the design document;
receiving, at the computing device, the augmented reality file from the central server; and
displaying, at the computing device, the augmented reality file on the mobile computing device.

9. The computer-implemented method of claim 8, further comprising displaying, at the computing device, additional augmented reality information corresponding to the design document.

10. The computer-implemented method of claim 7, further comprising utilizing a second marker to orient a view of displaying the augmented reality file on the mobile computing device.

11. A system comprising:
a computing device to receive a design file, receive an image file representing a three-dimensional (3D) model corresponding to the design file, generate an augmented reality file representing the two-dimensional design file, the augmented reality file linked to a marker uniquely identifying a location of the augmented reality file; and generating a copy of the design file, the copy including the marker.

12. The system of claim 11, further comprising a mobile computing device, the mobile computing device to scan the marker, retrieve the augmented reality file utilizing the scanner marker, store the augmented reality file in memory of the mobile computing device, and display the augmented reality file on a display of the mobile computing device.

13. The system of claim 11, wherein the computing device converts the image file representing the 3D model into the augmented reality file and stores the augmented reality file in a database server.

14. The system of claim 11, further comprising a printer, wherein the computing device transmits the copy of the design file to the printer, which prints a hard copy output of the design file, the marker being printed on the hard copy output.

15. The system of claim 11, further comprising a display of the computing device, wherein the computing device transmits a copy of the design file to the display, which generates a viewable version of an electronic document corresponding to the design file, the marker being visible within the viewable version of the electronic document.

16. The system of claim 12, wherein the augmented reality file further includes a reference point, the reference point identifying a viewing orientation for the image file representing the 3D model of the structure.

17. The system of claim 16, the computing device further generating a copy of the design file, the copy of the design file including the reference point.

18. The system of claim 17, the mobile computing device to scan the reference point on the copy of the design file and to orient the augmented reality file on the display to the identified viewing orientation for the augmented reality file.

19. The system of claim 11, the marker further comprising a link to the augmented reality file, the link being utilized to retrieve the augmented reality file from the central server to the mobile computing device.
